(19) United States
(12) Patent Application Publication
(10) Pub. No.: US 2026/0213488 A1
(43) Pub. Date: Jul. 23, 2026

(54) SEMICONDUCTOR LASER DEVICE

(71) Applicant: HAMAMATSU PHOTONICS K.K, Shizuoka (JP)

(72) Inventors: Junya MAEDA, Shizuoka (JP); Masashi KAMEI, Shizuoka (JP)

(21) Appl. No.: 19/143,128

(22) PCT Filed: Sep. 20, 2023
(86) PCT No.: PCT/JP2023/034115

§ 371 Date: Jun. 25, 2025

(30) Foreign Application Priority Data
Dec. 27, 2022 (JP) 2022-209495

(51) Int. Cl. H01S 5/02253; H01S 5/02326

(52) U.S. Cl. CPC H01S 5/02253; H01S 5/02326

(57) ABSTRACT

A semiconductor laser device includes a base, a semiconductor laser element disposed on the base, a lens configured to adjust a spread angle of laser light in a third direction perpendicular to first and second directions, a first support body supporting the lens with respect to the base, and a first bonding member bonding the lens and the first support body. The first support body has a first opening portion opened to first and second surfaces. At least a part of an inner opening of the first opening portion on the first surface side overlaps a first end surface of the lens when viewed from the second direction. The first bonding member is continuously disposed in at least a part of a region between the first end surface and the inner opening of the first opening portion and at least a part of a region in the first opening portion.

### TECHNICAL FIELD

The present disclosure relates to a semiconductor laser device.

### BACKGROUND ART

A semiconductor laser device including a base, a semiconductor laser element disposed on the base, a lens facing the semiconductor laser element, a support supporting the lens with respect to the base, and a bonding member bonding the lens and the support is known (see, for example, Patent Literature 1).

### CITATION LIST

### Patent Literature

Patent Literature 1: Japanese Unexamined Patent Publication No. 2014-170888

### SUMMARY OF INVENTION

### Technical Problem

In the semiconductor laser device as described above, when a portion, which is disposed in the region between the end surface of the lens and the support surface of the support, of the bonding member is thick, there is a concern that the axial deviation of the lens with respect to the semiconductor laser element due to the deformation of the portion (for example, swelling, thermal expansion, and thermal contraction) increases. On the other hand, when the portion of the bonding member disposed in the region between the end surface of the lens and the support surface of the support is thin, the amount of protrusion of the bonding member to the periphery increases by that thin thickness, there is a concern that the axial deviation of the lens with respect to the semiconductor laser element due to the deformation of the protruding portion of the bonding member increases.

An object of the present disclosure is to provide a semiconductor laser device capable of suppressing the axial deviation of a lens with respect to a semiconductor laser element.

### Solution to Problem

A semiconductor laser device of one aspect of the present disclosure is [1] “A semiconductor laser device including: a base; a semiconductor laser element disposed on the base and having at least one light-emitting point configured to emit laser light; a lens having a light input surface facing the at least one light-emitting point in a first direction, a light output surface located on a side opposite to the light input surface in the first direction, a first end surface located on one side in a second direction perpendicular to the first direction, and a second end surface located on the other side in the second direction, and configured to adjust a spread angle of the laser light in a third direction perpendicular to both the first direction and the second direction; a first support body having a first surface located on the first end surface side in the second direction and a second surface located on a side opposite to the first end surface in the second direction, and supporting the lens with respect to the base; and a first bonding member bonding the lens and the first support body, in which the first support body has a first opening portion opened to the first surface and the second surface, at least a part of an inner opening of the first opening portion on the first surface side overlaps the first end surface when viewed from the second direction, and the first bonding member is continuously disposed in at least a part of a region between the first end surface and the inner opening of the first opening portion and at least a part of a region in the first opening portion”.

In the semiconductor laser device described in [1], the first support body supporting the lens with respect to the base has the first opening portion opened to the first surface and the second surface, and at least a part of the inner opening of the first opening portion on the first surface side overlaps the first end surface of the lens when viewed from the second direction. In this state, the first bonding member is continuously disposed in at least a part of the region between the first end surface of the lens and the inner opening of the first opening portion and at least a part of the region in the first opening portion of the first support body. Thereby, it is possible to thin a portion, which is disposed in the region between the first end surface of the lens and the inner opening of the first opening portion, of the first bonding member while suppressing protrusion of the first bonding member from the region between the first end surface of the lens and the inner opening of the first opening portion to the periphery. Therefore, the axial deviation of the lens due to the deformation of the first bonding member is suppressed. Moreover, since a portion, which is disposed in the region in the first opening portion of the first support body, of the first bonding member functions as a core, the bonding strength between the lens and the first support body is improved, and the axial deviation of the lens in a direction perpendicular to the second direction is suppressed. As described above, according to the semiconductor laser device described in [1], the axial deviation of the lens with respect to the semiconductor laser element can be suppressed.

The semiconductor laser device of one aspect of the present disclosure may be [2] “The semiconductor laser device described in [1], in which the first bonding member is continuously disposed in at least a part of a region between the first end surface and the first surface, at least a part of the region between the first end surface and the inner opening of the first opening portion, and at least a part of the region in the first opening portion”. According to the semiconductor laser device described in [2], the bonding strength between the lens and the first support body can be further improved while suppressing the axial deviation of the lens in the direction perpendicular to the second direction.

The semiconductor laser device of one aspect of the present disclosure may be [3] “The semiconductor laser device described in [1] or [2], in which the first opening portion is a through hole opened to the first surface and the second surface”. According to the semiconductor laser device described in [3], since the first bonding member easily stays in a region in the through hole, the bonding strength between the lens and the first support body can be improved.

The semiconductor laser device of one aspect of the present disclosure may be [4] “The semiconductor laser device described in [1] or [2], in which the first opening portion is a notch opened to the first surface and the second surface and opened to a third surface connecting the first surface and the second surface”. According to the semiconductor laser device described in [4], since the first bonding member easily escapes from the region between the first end surface of the lens and the inner opening of the first opening portion to the notch side, it is possible to suppress protrusion of the first bonding member from the region between the first end surface of the lens and the inner opening of the first opening portion to the periphery.

The semiconductor laser device of one aspect of the present disclosure may be [5] “The semiconductor laser device described in [4], in which the notch is opened to a region of the third surface located on a side opposite to the semiconductor laser element in the first direction when viewed from the second direction”. According to the semiconductor laser device described in [5], even when a portion, which is disposed in the region in the notch, of the first bonding member is deformed, the axial deviation of the lens particularly in the third direction is suppressed, so that the lens adjusting a spread angle of the laser light in the third direction can function suitably.

The semiconductor laser device of one aspect of the present disclosure may be [6] “The semiconductor laser device described in [4], in which the notch is opened to a region of the third surface located on one side in the third direction when viewed from the second direction”. According to the semiconductor laser device described in [6], even when the first bonding member protrudes from the region in the notch to the region on the third surface of the first support body, the first bonding member can be prevented from adhering to the light input surface and the light output surface of the lens.

The semiconductor laser device of one aspect of the present disclosure may be [7] “The semiconductor laser device described in any one of [1] to [6], in which the first bonding member reaches an outer opening of the first opening portion on the second surface side”. According to the semiconductor laser device described in [7], since the portion, which is disposed in the region in the first opening portion of the first support body, of the first bonding member functions as a core, the bonding strength between the lens and the first support body can be improved, and the axial deviation of the lens in the direction perpendicular to the second direction can be suppressed.

The semiconductor laser device of one aspect of the present disclosure may be [8] “The semiconductor laser device described in any one of [1] to [7], in which the first bonding member is continuously disposed in at least a part of the region between the first end surface and the inner opening of the first opening portion, at least a part of the region in the first opening portion, and at least a part of a region on the second surface”. According to the semiconductor laser device described in [8], since a portion, which is disposed in the region on the second surface of the first support body, of the first bonding member functions as an anchor (stopper), the bonding strength between the lens and the first support body can be improved, and the axial deviation of the lens in the direction perpendicular to the second direction can be suppressed.

The semiconductor laser device of one aspect of the present disclosure may be [9] “The semiconductor laser device described in [8], in which in the first bonding member, a portion disposed in at least a part of the region between the first end surface and the inner opening of the first opening portion is thinner than a portion disposed in at least a part of the region on the second surface”. According to the semiconductor laser device described in [9], since the thickness of the portion, which is disposed in the region between the first end surface of the lens and the inner opening of the first opening portion, of the first bonding member hardly varies, the axial deviation of the lens due to the deformation of the first bonding member can be suppressed. Furthermore, since the portion, which is disposed in the region on the second surface of the first support body, of the first bonding member functions as an anchor, the bonding strength between the lens and the first support body can be improved, and the axial deviation of the lens in the direction perpendicular to the second direction can be suppressed.

The semiconductor laser device of one aspect of the present disclosure may be [10] “The semiconductor laser device described in any one of [1] to [9], in which the entire inner opening of the first opening portion overlaps the first end surface when viewed from the second direction”. According to the semiconductor laser device described in , since the first bonding member easily escapes from the region between the first end surface of the lens and the inner opening of the first opening portion to the region in the first opening portion, it is possible to suppress protrusion of the first bonding member from the region between the first end surface of the lens and the inner opening of the first opening portion to the periphery.

The semiconductor laser device of one aspect of the present disclosure may be [11] “The semiconductor laser device described in any one of [1] to [10], in which the first support body has optical transparency”. According to the semiconductor laser device described in [11], it is possible to confirm the state of the portion, which is disposed in the region between the first end surface of the lens and the inner opening of the first opening portion, of the first bonding member and the portion, which is disposed in the region in the first opening portion of the first support body, of the first bonding member.

The semiconductor laser device of one aspect of the present disclosure may be [12] “The semiconductor laser device described in any one of [1] to [11], in which a thickness of the first support body in the second direction is 2 mm or less”. According to the semiconductor laser device described in [12], it is possible to reliably dispose the first bonding member in the region in the first opening portion of the first support body while reducing the amount of the first bonding member.

The semiconductor laser device of one aspect of the present disclosure may be [13] “The semiconductor laser device described in any one of [1] to [12], in which at least a part of the light output surface is offset from the first support body when viewed from the second direction”. According to the semiconductor laser device described in , the first bonding member can be prevented from adhering to the light output surface of the lens.

The semiconductor laser device of one aspect of the present disclosure may be [14] “The semiconductor laser device described in any one of [1] to [13], in which a width of the inner opening of the first opening portion in the first direction is equal to or more than a width of the inner opening of the first opening portion in the third direction”. According to the semiconductor laser device described in [14], even when a portion, which is disposed in a region in the first opening portion, of the first bonding member is deformed, the axial deviation of the lens particularly in the third direction is suppressed, so that the lens adjusting a spread angle of the laser light in the third direction can function suitably.

The semiconductor laser device of one aspect of the present disclosure may be [15] “The semiconductor laser device described in any one of [1] to [14], further including a second bonding member bonding the base and the first support body formed separately from the base, in which the first support body has a second opening portion opened to the first surface and the second surface, at least a part of an inner opening of the second opening portion on the first surface side overlaps a side surface of the base when viewed from the second direction, and the second bonding member is continuously disposed in at least a part of a region between the side surface and the inner opening of the second opening portion and at least a part of a region in the second opening portion”. According to the semiconductor laser device described in [15], structure (for example, shape and material) of each of the base and the first support body can be appropriately configured. Furthermore, since the second bonding member is disposed in the region in the second opening portion of the first support body, the bonding strength between the base and the first support body can be improved.

The semiconductor laser device of one aspect of the present disclosure may be [16] “The semiconductor laser device described in [15], in which the second bonding member is continuously disposed in at least a part of a region between the side surface and the first surface, at least a part of the region between the side surface and the inner opening of the second opening portion, and at least a part of the region in the second opening portion”. According to the semiconductor laser device described in [16], the bonding strength between the base and the first support body can be further improved.

The semiconductor laser device of one aspect of the present disclosure may be [17] “The semiconductor laser device described in or [16], in which in the first surface, an area of a region overlapping the side surface when viewed from the second direction is larger than an area of a region overlapping the first end surface when viewed from the second direction, and an area of the inner opening of the second opening portion is larger than an area of the inner opening of the first opening portion”. According to the semiconductor laser device described in [17], the stability of the support for the first support body and the lens can be improved. Furthermore, for example, in a case where the base and the first support body are bonded after the lens and the first support body are bonded, even when the amount of the second bonding member is increased so that the first support body for alignment of the lens with respect to the semiconductor laser element can be easily moved, it is possible to suppress protrusion of the second bonding member from the region overlapping the side surface when viewed from the second direction of the first surface of the first support body.

The semiconductor laser device of one aspect of the present disclosure may be [18] “The semiconductor laser device described in any one of [1] to [17], further including: a second support body having a fourth surface located on the second end surface side in the second direction and a fifth surface located on a side opposite to the second end surface in the second direction, and supporting the lens with respect to the base; and a third bonding member bonding the lens and the second support body, in which the second support body has a third opening opened to the fourth surface and the fifth surface, at least a part of an inner opening of the third opening on the fourth surface side overlaps the second end surface when viewed from the second direction, and the third bonding member is continuously disposed in at least a part of a region between the second end surface and the inner opening of the third opening and at least a part of a region in the third opening”. According to the semiconductor laser device described in [18], the stability of supporting the lens can be further improved, and the axial deviation of the lens in the direction perpendicular to the second direction can be more reliably suppressed.

The semiconductor laser device of one aspect of the present disclosure may be [19] “The semiconductor laser device described in [18], in which the third bonding member is continuously disposed in at least a part of a region between the second end surface and the fourth surface, at least a part of the region between the second end surface and the inner opening of the third opening, and at least a part of the region in the third opening”. According to the semiconductor laser device described in [19], the bonding strength between the lens and the second support body can be further improved while suppressing the axial deviation of the lens in a direction perpendicular to the second direction.

The semiconductor laser device of one aspect of the present disclosure may be [20] “The semiconductor laser device described in any one of [1] to [19], in which the semiconductor laser element has a plurality of light-emitting points arranged in the second direction, the lens extends in the second direction, and the light input surface faces the plurality of light-emitting points in the first direction”. According to the semiconductor laser device described in [20], it is possible to suppress variation in the spread angle of the laser light in the third direction for the laser light emitted from each of the plurality of light-emitting points.

### Advantageous Effects of Invention

According to the present disclosure, it is possible to provide a semiconductor laser device capable of suppressing the axial deviation of a lens with respect to a semiconductor laser element.

### BRIEF DESCRIPTION OF DRAWINGS

FIG. 1 is a plan view of a part of a semiconductor laser device of one embodiment.

FIG. 2 is a side view of a part of the semiconductor laser device illustrated in FIG. 1.

FIG. 3 is a perspective view of a semiconductor laser element illustrated in FIG. 1.

FIG. 4 is a side view of a first support body illustrated in FIG. 1.

FIG. 5 is a cross-sectional view of the first support body taken along line V-V illustrated in FIG. 4.

FIG. 6 is a side view of a second support body illustrated in FIG. 1.

FIG. 7 is a cross-sectional view of the second support body taken along line VII-VII illustrated in FIG. 6.

FIG. 8 is a side view of the first support body of a modification.

FIG. 9 is a side view of the first support body of a modification.

### DESCRIPTION OF EMBODIMENTS

Hereinafter, embodiments of the present disclosure will be described in detail with reference to the accompanying drawings. Note that, in the drawings, the same or corresponding parts are denoted by the same reference signs, and redundant description will be omitted.

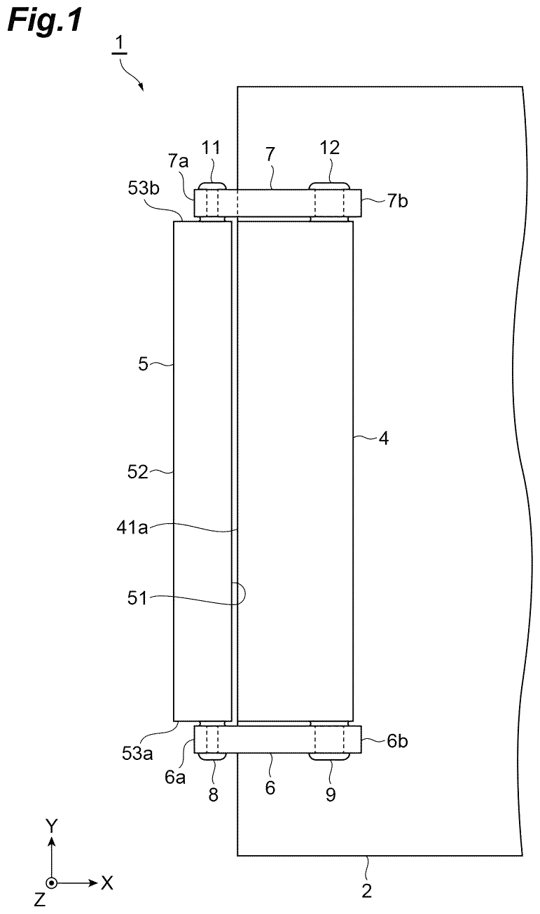

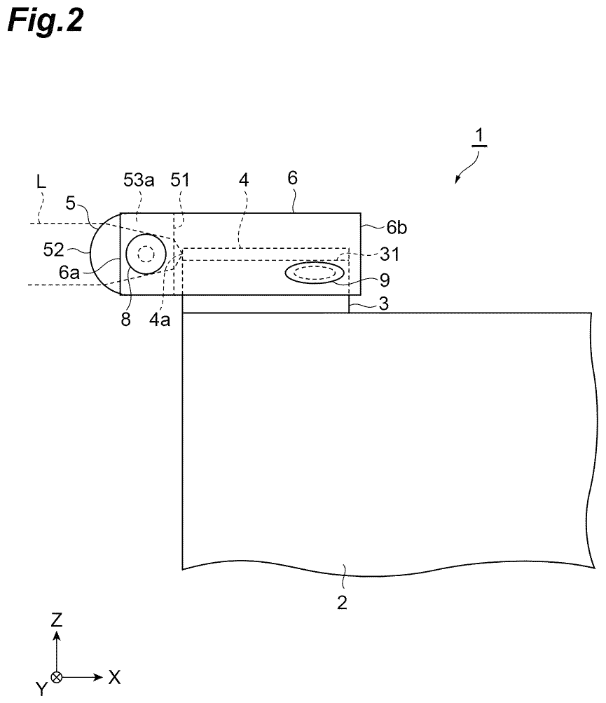

As illustrated in FIGS. 1 and 2, a semiconductor laser device 1 includes a heat sink 2, a submount (base) 3, a semiconductor laser element 4, a lens 5, a first support body 6, and a second support body 7. The lens 5 and the first support body 6 are bonded to each other by the first bonding member 8. The submount 3 and the first support body 6 are bonded to each other by a second bonding member 9. The lens 5 and the second support body 7 are bonded to each other by a third bonding member 11. The submount 3 and the second support body 7 are bonded to each other by a fourth bonding member 12. The first bonding member 8, the second bonding member 9, the third bonding member 11, and the fourth bonding member 12 are, for example, photocurable resins. As the photocurable resin, an ultraviolet curable resin, a visible light curable resin, or the like can be used. Note that the first bonding member 8, the second bonding member 9, the third bonding member 11, and the fourth bonding member 12 may be thermosetting resins.

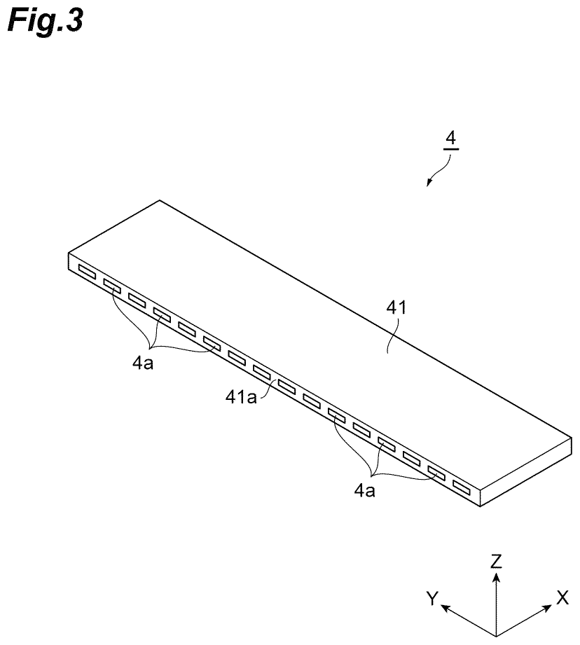

As illustrated in FIG. 3, the semiconductor laser element 4 includes a semiconductor laminate 41, and an anode and a cathode (not illustrated). The semiconductor laminate 41 is formed in a rectangular plate shape in which a Z direction is a thickness direction, an X direction is a short side direction, and a Y direction is a long side direction, for example, by laminating a plurality of layers (such as an active layer and cladding layer on both sides of the active layer) made of a compound semiconductor. The compound semiconductor is, for example, GaAs, AlGaAs, GaN, AlGaN, or a mixed crystal of any of these and In. The semiconductor laser element 4 has a plurality of light-emitting points 4a emitting laser light. The plurality of light-emitting points 4a are arranged in a line in the Y direction on a light-emitting surface 41a of the semiconductor laminate 41 perpendicular to the X direction. As an example, the thickness of the semiconductor laser element 4 in the Z direction is about 0.15 mm, the width of the semiconductor laser element 4 in the X direction is about 2 mm, and the width of the semiconductor laser element 4 in the Y direction is about 10 mm.

In the semiconductor laser element 4 configured as described above, the laser light is emitted from each light-emitting point 4a with the Z direction as a fast axis direction and the Y direction as a slow axis direction. Note that supplying of power to the anode and the cathode (not illustrated) of the semiconductor laser element 4 can be realized by a known configuration.

As illustrated in FIGS. 1 and 2, the semiconductor laser element 4 is disposed on the heat sink 2 with the submount 3 interposed therebetween. That is, the semiconductor laser element 4 is disposed on the submount 3. In the present embodiment, the semiconductor laser element 4 is fixed onto a mounting surface 31 of the submount 3 perpendicular to the Z direction. The heat sink 2 is formed in a block shape by CuW, for example. The submount 3 is formed of, for example, Al₂O₃, SiC, or CuW in a rectangular plate shape in which a Z direction is a thickness direction, an X direction is a short side direction, and a Y direction is a long side direction. As an example, the thickness of the submount 3 in the Z direction is about 0.6 mm, the width of the submount 3 in the X direction is about 2 mm, and the width of the submount 3 in the Y direction is about 10 mm. In the present embodiment, an outer edge of the semiconductor laser element 4 coincides with an outer edge of the submount 3 when viewed from the Z direction.

The lens 5 extends in the Y direction, and adjusts a spread angle of laser light L in at least the Z direction (a third direction perpendicular to both a first direction and a second direction), the laser light L being emitted from each light-emitting point 4a. The lens 5 has a light input surface 51, a light output surface 52, a first end surface 53a, and a second end surface 53b. The light input surface 51 faces the plurality of light-emitting points 4a in the X direction (first direction). A gap is formed between the light input surface 51 of the lens 5 and the light-emitting surface 41a of the semiconductor laser element 4. The distance between the light input surface 51 of the lens 5 and the light-emitting surface 41a of the semiconductor laser element 4 is, for example, about 0.1 mm. The light output surface 52 is located on a side opposite to the light input surface 51 in the X direction. The first end surface 53a is located on one side in the Y direction (the second direction perpendicular to the first direction). The second end surface 53b is located on the other side in the Y direction.

The lens 5 is, for example, a fast-axis collimation lens formed of high refractive index glass. As an example, the light input surface 51 is a flat surface perpendicular to the X direction, and the light output surface 52 is a part of a cylindrical surface having a center line parallel to the Y direction. As an example, the width of the lens 5 in the Z direction is about 1 mm, the width of the lens 5 in the X direction is about 1 mm, and the width of the lens 5 in the Y direction is about 10 mm. In the present embodiment, the lens 5 adjusts a spread angle of the laser light L in the Z direction and emits laser light collimated in the Z direction. Note that the lens 5 may have, for example, a cylindrical shape. Also in this case, a region of the outer peripheral surface of the cylinder on the semiconductor laser element 4 side in the X direction is the light input surface 51, and a region of the outer peripheral surface of the cylinder on a side opposite to the semiconductor laser element 4 in the X direction is the light output surface 52. Further, in this case, the light input surface 51 and the light output surface 52 may be continuous (that is, it may be formed as a surface smoothly connected so as not to have a corner portion).

The first support body 6 and the second support body 7 are formed separately from the submount 3, and support the lens 5 with respect to the submount 3. The first support body 6 is bonded to the lens 5 by the first bonding member 8 at a portion on a distal end 6a side, and is bonded to the submount 3 by the second bonding member 9 at a portion on a proximal end 6b side. The second support body 7 is bonded to the lens 5 by the third bonding member 11 at a portion on a distal end 7a side, and is bonded to the submount 3 by the fourth bonding member 12 at a portion on a proximal end 7b side. At least a part of the light output surface 52 of the lens 5 is offset from the first support body 6 and the second support body 7 when viewed from the Y direction. Specifically, at least a part of the light output surface 52 of the lens 5 protrudes from the distal end 6a of the first support body 6 and the distal end 7a of the second support body 7 to a side opposite to the semiconductor laser element 4 in the X direction when viewed from the Y direction.

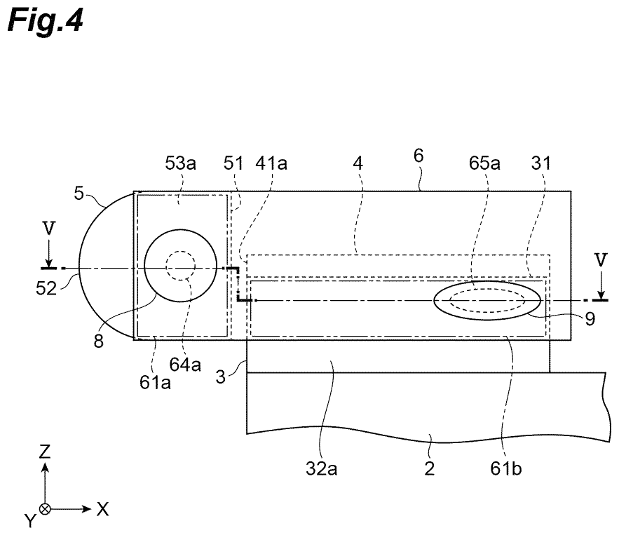

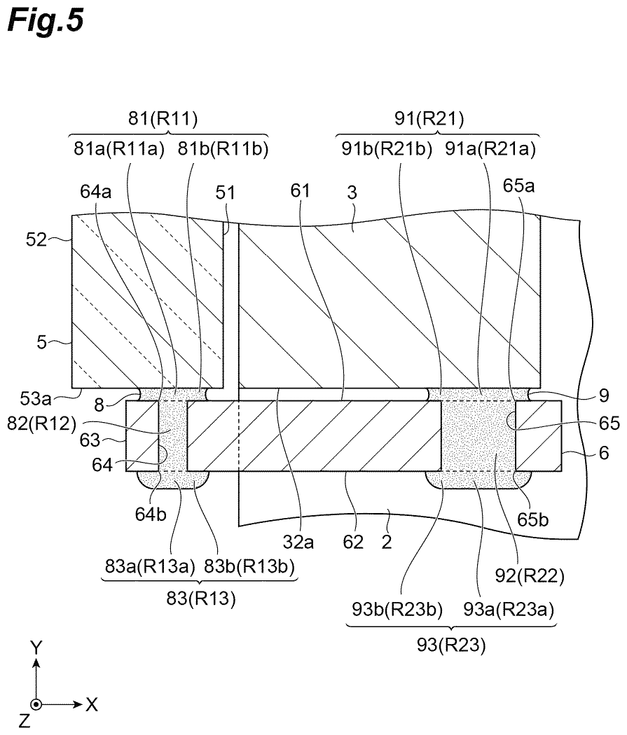

As illustrated in FIGS. 4 and 5, the first support body 6 has a first surface 61, a second surface 62, and a third surface 63. The first surface 61 is located on a side of the first end surface 53a of the lens 5 and a first side surface (side surface) 32a of the submount 3 in the Y direction. The second surface 62 is located on a side opposite to the first end surface 53a of the lens 5 and the first side surface 32a of the submount 3 in the Y direction. The third surface 63 is a surface connecting the first surface 61 and the second surface 62. The thickness of the first support body 6 (that is, the distance between the first surface 61 and the second surface 62) in the Y direction is 2 mm or less. The first support body 6 has optical transparency (for example, ultraviolet light transmissivity and/or visible light transmissivity). The first support body 6 is formed of, for example, BK7, synthetic quartz, or borosilicate glass in a rectangular parallelepiped shape. As an example, the width of the first support body 6 in the Z direction is about 1 mm, the width of the first support body 6 in the X direction is about 6 mm, and the width of the first support body 6 in the Y direction is about 1 mm. Note that, from the viewpoint of securing the strength of the first support body 6 and securing a space in which the first bonding member 8 is disposed in a first opening portion 64 described later, the thickness of the first support body 6 is preferably 0.5 mm or more and more preferably 1 mm or more.

The first support body 6 has a first opening portion 64 and a second opening portion 65. The first opening portion 64 and the second opening portion 65 are through holes opened to the first surface 61 and the second surface 62, respectively. The through hole is formed in a cylindrical shape having a center line parallel to the Y direction, for example. An inner opening 64a of the first opening portion 64 on the first surface 61 side is included in the first end surface 53a of the lens 5 when viewed from the Y direction. That is, when viewed from the Y direction, the entire inner opening 64a of the first opening portion 64 overlaps the first end surface 53a of the lens 5. The width of the inner opening 64a in the X direction is equal to the width of the inner opening 64a in the Z direction. The inner opening 64a of the first opening portion 64 has, for example, a circular shape having a diameter of about 0.2 mm. An outer opening 64b of the first opening portion 64 has, for example, a circular shape having a diameter of about 0.2 mm. An inner opening 65a of the second opening portion 65 on the first surface 61 side is included in the first side surface 32a of the submount 3 when viewed from the Y direction. That is, when viewed from the Y direction, the entire inner opening 65a of the second opening portion 65 overlaps the first side surface 32a of the submount 3. The width of the inner opening 65a in the X direction is larger than the width of the inner opening 65a in the Z direction. Each of the inner opening 65a and an outer opening 65b of the second opening portion 65 has, for example, an elliptical shape having a width of about 0.4 mm in the X direction and a width of about 0.2 mm in the Z direction. The second opening portion 65 is located on the submount 3 side with respect to the lens 5 by a position of half the width of the first support body 6 in the X direction.

The first bonding member 8 is continuously disposed in at least a part of a region R11, at least a part of a region R12, and at least a part of a region R13. The region R11 is a region between the first end surface 53a of the lens 5 and a plane including the first surface 61 of the first support body 6. The region R12 is a region in the first opening portion 64 of the first support body 6. The region R13 is a region on a plane including the second surface 62 of the first support body 6. That is, the first bonding member 8 includes a portion 81 disposed in the region R11, a portion 82 disposed in the region R12, and a portion 83 disposed in the region R13, and these portions 81, 82, and 83 are integrally formed. In the present embodiment, the first bonding member 8 is disposed in the entire region R12 in the first opening portion 64.

In the present embodiment, the region R11 includes a region R11a and a region R11b. The region R11a is a region between the first end surface 53a of the lens 5 and the inner opening 64a of the first opening portion 64. In other words, the region R11a is a region overlapping the inner opening 64a of the first opening portion 64 when viewed from the Y direction in the region R11. The region R11b is a region between the first end surface 53a of the lens 5 and the first surface 61 of the first support body 6. In other words, the region R11b is an annular region surrounding the inner opening 64a of the first opening portion 64 when viewed from the Y direction in the region R11. The portion 81 of the first bonding member 8 includes a portion 81 a disposed in the region R11a and an annular portion 81b disposed in the region R11b. The region R13 includes a region R13a and a region R13b. The region R13a is a region outside the outer opening 64b of the first opening portion 64 (on a side opposite to the first end surface 53a in the Y direction). In other words, the region R13a is a region overlapping the outer opening 64b of the first opening portion 64 when viewed from the Y direction in the region R13. The region R13b is a region on the second surface 62 of the first support body 6. In other words, the region R13b is an annular region surrounding the outer opening 64b of the first opening portion 64 when viewed from the Y direction in the region R13. The portion 83 of the first bonding member 8 includes a portion 83a disposed in the region R13a and an annular portion 83b disposed in the region R13b. 81a, 81b, 82, 83a, and 83b of the first bonding member 8 are integrally formed. As an example, the width of the portion 81b in the radial direction (the distance between the inner edge of the portion 81b and the outer edge of the portion 81b when viewed from the Y direction) is about 0.1 to 0.2 mm.

In the first bonding member 8, the portion 81 (that is, the portions 81a and 81b) disposed in the region R11 between the first end surface 53a of the lens 5 and the plane including the first surface 61 of the first support body 6 is thinner than the portion 83 (that is, the portions 83a and 83b) disposed in the region R13 on the plane including the second surface 62 of the first support body 6. That is, the maximum value of the thickness of the portion 81 in the Y direction (that is, the distance between the first end surface 53a of the lens 5 and the first surface 61 of the first support body 6) is smaller than the maximum value of the thickness of the portion 83 in the Y direction. As an example, the maximum value of the thickness of the portion 81 in the Y direction is about 0.1 mm, and the maximum value of the thickness of the portion 83 in the Y direction is about 0.2 mm.

The second bonding member 9 is continuously disposed in at least a part of a region R21, at least a part of a region R22, and at least a part of a region R23. The region R21 is a region between the first side surface 32a of the submount 3 and a plane including the first surface 61 of the first support body 6. The region R22 is a region in the second opening portion 65 of the first support body 6. The region R23 is a region on a plane including the second surface 62 of the first support body 6. That is, the second bonding member 9 includes a portion 91 disposed in the region R21, a portion 92 disposed in the region R22, and a portion 93 disposed in the region R23, and these portions 91, 92, and 93 are integrally formed. In the present embodiment, the second bonding member 9 is disposed in the entire region R22 in the second opening portion 65.

In the present embodiment, the region R21 includes a region R21a and a region R21b. The region R21a is a region between the first side surface 32a of the submount 3 and the inner opening 65a of the second opening portion 65. In other words, the region R21a is a region overlapping the inner opening 65a of the second opening portion 65 when viewed from the Y direction in the region R21. The region R21b is a region between the first side surface 32a of the submount 3 and the first surface 61 of the first support body 6. In other words, the region R21b is an annular region surrounding the inner opening 65a of the second opening portion 65 when viewed from the Y direction in the region R21. The portion 91 of the second bonding member 9 includes a portion 91a disposed in the region R21a and an annular portion 91b disposed in the region R21b. The region R23 includes a region R23a and a region R23b. The region R23a is a region outside the outer opening 65b of the second opening portion 65 (on a side opposite to the first side surface 32a in the Y direction). In other words, the region R23a is a region overlapping the outer opening 65b of the second opening portion 65 when viewed from the Y direction in the region R23. The region R23b is a region on the second surface 62 of the first support body 6. In other words, the region R23b is an annular region surrounding the outer opening 65b of the second opening portion 65 when viewed from the Y direction in the region R23. The portion 93 of the second bonding member 9 includes a portion 93a disposed in the region R23a and an annular portion 93b disposed in the region R23b. 91a, 91b, 92, 93a, and 93b of the second bonding member 9 are integrally formed. As an example, the width of the portion 91b in the radial direction (the distance between the inner edge of the portion 91b and the outer edge of the portion 91b when viewed from the Y direction) is about 0.1 to 0.2 mm.

In the second bonding member 9, the portion 91 (that is, the portions 91a and 91b) disposed in the region R21 between the first side surface 32a of the submount 3 and the plane including the first surface 61 of the first support body 6 is thinner than the portion 93 (that is, the portions 93a and 93b) disposed in the region R23 on the plane including the second surface 62 of the first support body 6. That is, the maximum value of the thickness of the portion 91 in the Y direction (that is, the distance between the first side surface 32a of the submount 3 and the first surface 61 of the first support body 6) is smaller than the maximum value of the thickness of the portion 93 in the Y direction.

In the first surface 61 of the first support body 6, the area of a region 61b overlapping the first side surface 32a of the submount 3 when viewed from the Y direction is larger than the area of a region 61a overlapping the first end surface 53a of the lens 5 when viewed from the Y direction. The area of the inner opening 65a of the second opening portion 65 is larger than the area of the inner opening 64a of the first opening portion 64.

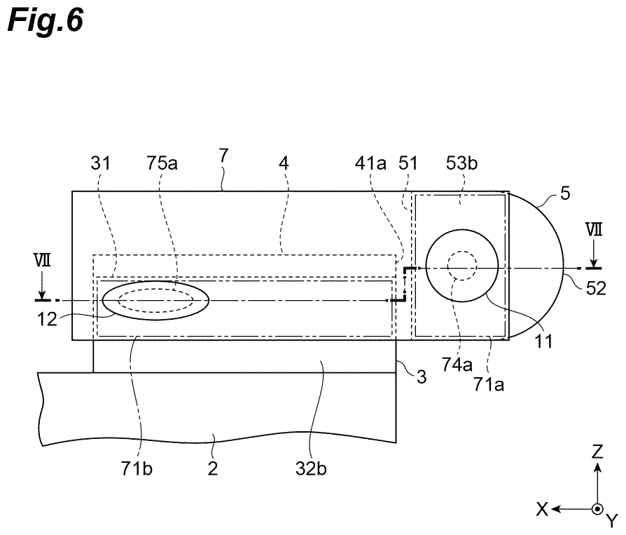

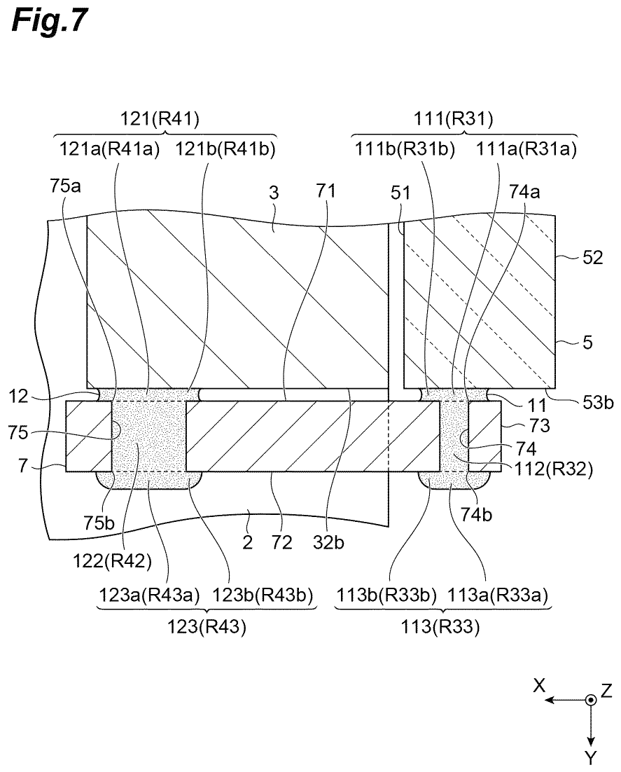

As illustrated in FIGS. 6 and 7, the second support body 7 has a fourth surface 71, a fifth surface 72, and a sixth surface 73. The fourth surface 71 is located on a side of the second end surface 53b of the lens 5 and a second side surface 32b of the submount 3 in the Y direction. The fifth surface 72 is located on a side opposite to the second end surface 53b of the lens 5 and the second side surface 32b of the submount 3 in the Y direction. The sixth surface 73 is a surface connecting the fourth surface 71 and the fifth surface 72. The thickness of the second support body 7 (that is, the distance between the fourth surface 71 and the fifth surface 72) in the Y direction is 2 mm or less. The second support body 7 has optical transparency (for example, ultraviolet light transmissivity and/or visible light transmissivity). The second support body 7 is formed of, for example, BK7, synthetic quartz, or borosilicate glass in a rectangular parallelepiped shape. As an example, the width of the second support body 7 in the Z direction is about 1 mm, the width of the second support body 7 in the X direction is about 6 mm, and the width of the second support body 7 in the Y direction is about 1 mm. Note that, from the viewpoint of securing the strength of the second support body 7 and securing a space in which the third bonding member 11 is disposed in a third opening 74 described later, the thickness of the second support body 7 is preferably 0.5 mm or more and more preferably 1 mm or more.

The second support body 7 has a third opening 74 and a fourth opening 75. The third opening 74 and the fourth opening 75 are through holes opened to the fourth surface 71 and the fifth surface 72, respectively. The through hole is formed in a cylindrical shape having a center line parallel to the Y direction, for example. An inner opening 74a of the third opening 74 on the fourth surface 71 side is included in the second end surface 53b of the lens 5 when viewed from the Y direction. That is, when viewed from the Y direction, the entire inner opening 74a of the third opening 74 overlaps the second end surface 53b of the lens 5. The width of the inner opening 74a in the X direction is equal to the width of the inner opening 74a in the Z direction. The inner opening 74a of the third opening 74 has, for example, a circular shape having a diameter of about 0.2 mm. An outer opening 74b of the third opening 74 has, for example, a circular shape having a diameter of about 0.2 mm. An inner opening 75a of the fourth opening 75 on the fourth surface 71 side is included in the second side surface 32b of the submount 3 when viewed from the Y direction. That is, when viewed from the Y direction, the entire inner opening 75a of the fourth opening 75 overlaps the second side surface 32b of the submount 3. The width of the inner opening 75a in the X direction is larger than the width of the inner opening 75a in the Z direction. Each of the inner opening 75a and an outer opening 75b of the fourth opening 75 has, for example, an elliptical shape having a width of about 0.4 mm in the X direction and a width of about 0.2 mm in the Z direction. The fourth opening 75 is located on the submount 3 side with respect to the lens 5 by a position of half the width of the second support body 7 in the X direction.

The third bonding member 11 is continuously disposed in at least a part of a region R31, at least a part of a region R32, and at least a part of a region R33. The region R31 is a region between the second end surface 53b of the lens 5 and a plane including the fourth surface 71 of the second support body 7. The region R32 is a region in the third opening 74 of the second support body 7. The region R33 is a region on a plane including the fifth surface 72 of the second support body 7. That is, the third bonding member 11 includes a portion 111 disposed in the region R31, a portion 112 disposed in the region R32, and a portion 113 disposed in the region R33, and these portions 111, 112, and 113 are integrally formed. In the present embodiment, the third bonding member 11 is disposed in the entire region R32 in the third opening 74.

In the present embodiment, the region R31 includes a region R31a and a region R31b. The region R31a is a region between the second end surface 53b of the lens 5 and the inner opening 74a of the third opening 74. In other words, the region R31a is a region overlapping the inner opening 74a of the third opening 74 when viewed from the Y direction in the region R31. The region R31b is a region between the second end surface 53b of the lens 5 and the fourth surface 71 of the second support body 7. In other words, the region R31b is an annular region surrounding the inner opening 74a of the third opening 74 when viewed from the Y direction in the region R31. The portion 111 of the third bonding member 11 includes a portion 111a disposed in the region R31a and an annular portion 111b disposed in the region R31b. The region R33 includes a region R33a and a region R33b. The region R33a is a region outside the outer opening 74b of the third opening 74 (on a side opposite to the second end surface 53b in the Y direction). In other words, the region R33a is a region overlapping the outer opening 74b of the third opening 74 when viewed from the Y direction in the region R33. The region R33b is a region on the fifth surface 72 of the second support body 7. In other words, the region R33b is an annular region surrounding the outer opening 74b of the third opening 74 when viewed from the Y direction in the region R33. The portion 113 of the third bonding member 11 includes a portion 113a disposed in the region R33a and an annular portion 113b disposed in the region R33b. 111a, 111b, 112, 113a, and 113b of the third bonding member 11 are integrally formed. As an example, the width of the portion 111b in the radial direction (the distance between the inner edge of the portion 111b and the outer edge of the portion 111b when viewed from the Y direction) is about 0.1 to 0.2 mm.

In the third bonding member 11, the portion 111 (that is, the portions 111a and 111b) disposed in the region R31 between the second end surface 53b of the lens 5 and the plane including the fourth surface 71 of the second support body 7 is thinner than the portion 113 (that is, the portions 113a and 113b) disposed in the region R33 on the plane including the fifth surface 72 of the second support body 7. That is, the maximum value of the thickness of the portion 111 in the Y direction (that is, the distance between the second end surface 53b of the lens 5 and the fourth surface 71 of the second support body 7) is smaller than the maximum value of the thickness of the portion 113 in the Y direction. As an example, the maximum value of the thickness of the portion 111 in the Y direction is about 0.1 mm, and the maximum value of the thickness of the portion 113 in the Y direction is about 0.2 mm.

The fourth bonding member 12 is continuously disposed in at least a part of a region R41, at least a part of a region R42, and at least a part of a region R43. The region R41 is a region between the second side surface 32b of the submount 3 and a plane including the fourth surface 71 of the second support body 7. The region R42 is a region in the fourth opening 75 of the second support body 7. The region R43 is a region on a plane including the fifth surface 72 of the second support body 7. That is, the fourth bonding member 12 includes a portion 121 disposed in the region R41, a portion 122 disposed in the region R42, and a portion 123 disposed in the region R43, and these portions 121, 122, and 123 are integrally formed. In the present embodiment, the fourth bonding member 12 is disposed in the entire region R42 in the fourth opening 75.

In the present embodiment, the region R41 includes a region R41a and a region R41b. The region R41a is a region between the second side surface 32b of the submount 3 and the inner opening 75a of the fourth opening 75. In other words, the region R41a is a region overlapping the inner opening 75a of the fourth opening 75 when viewed from the Y direction in the region R41. The region R41b is a region between the second side surface 32b of the submount 3 and the fourth surface 71 of the second support body 7. In other words, the region R41b is an annular region surrounding the inner opening 75a of the fourth opening 75 when viewed from the Y direction in the region R41. The portion 121 of the fourth bonding member 12 includes a portion 121a disposed in the region R41a and an annular portion 121b disposed in the region R41b. The region R43 includes a region R43a and a region R43b. The region R43a is a region outside the outer opening 75b of the fourth opening 75 (on a side opposite to the second side surface 32b in the Y direction). In other words, the region R43a is a region overlapping the outer opening 75b of the fourth opening 75 when viewed from the Y direction in the region R43. The region R43b is a region on the fifth surface 72 of the second support body 7. In other words, the region R43b is an annular region surrounding the outer opening 75b of the fourth opening 75 when viewed from the Y direction in the region R43. The portion 123 of the fourth bonding member 12 includes a portion 123a disposed in the region R43a and an annular portion 123b disposed in the region R43b. 121a, 121b, 122, 123a, and 123b of the fourth bonding member 12 are integrally formed. As an example, the width of the portion 121b in the radial direction (the distance between the inner edge of the portion 121b and the outer edge of the portion 121b when viewed from the Y direction) is about 0.1 to 0.2 mm.

In the fourth bonding member 12, the portion 121 (that is, the portions 121a and 121b) disposed in the region R41 between the second side surface 32b of the submount 3 and the plane including the fourth surface 71 of the second support body 7 is thinner than the portion 123 (that is, the portions 123a and 123b) disposed in the region R43 on the plane including the fifth surface 72 of the second support body 7. That is, the maximum value of the thickness of the portion 121 in the Y direction (that is, the distance between the second side surface 32b of the submount 3 and the fourth surface 71 of the second support body 7) is smaller than the maximum value of the thickness of the portion 123 in the Y direction.

In the fourth surface 71 of the second support body 7, the area of a region 71b overlapping the second side surface 32b of the submount 3 when viewed from the Y direction is larger than the area of a region 71a overlapping the second end surface 53b of the lens 5 when viewed from the Y direction. The area of the inner opening 75a of the fourth opening 75 is larger than the area of the inner opening 74a of the third opening 74.

As described above, in the semiconductor laser device 1, the first support body 6 supporting the lens 5 with respect to the submount 3 has the first opening portion 64 opened to the first surface 61 and the second surface 62, and the entire inner opening 64a of the first opening portion 64 overlaps the first end surface 53a of the lens 5 when viewed from the Y direction. In this state, the first bonding member 8 is continuously disposed in at least a part of the region R11a between the first end surface 53a of the lens 5 and the inner opening 64a of the first opening portion 64, at least a part of the region R12 in the first opening portion 64 of the first support body 6, and at least a part of the region R13b on the second surface 62 of the first support body 6. Thereby, it is possible to thin the portion 81a, which is disposed in the region R11a between the first end surface 53a of the lens 5 and the inner opening 64a of the first opening portion 64, of the first bonding member 8 while suppressing protrusion of the first bonding member 8 from the region R11a between the first end surface 53a of the lens 5 and the inner opening 64a of the first opening portion 64 to the periphery (that is, while suppressing the amount of the portion 81b disposed in the region R11b between the first end surface 53a of the lens 5 and the first surface 61 of the first support body 6). Therefore, the axial deviation of the lens 5 due to the deformation of the first bonding member 8(for example, swelling, thermal expansion, and thermal contraction) is suppressed. Moreover, since the portion 82, which is disposed in the region R12 in the first opening portion 64 of the first support body 6, of the first bonding member 8 functions as a core and the portion 83b, which is disposed in the region R13b on the second surface 62 of the first support body 6, of the first bonding member 8 functions as an anchor (stopper), the bonding strength between the lens 5 and the first support body 6 is improved, and the axial deviation of the lens 5 in a direction perpendicular to the Y direction is suppressed.

Similarly, in the semiconductor laser device 1, the second support body 7 supporting the lens 5 with respect to the submount 3 has the third opening 74 opened to the fourth surface 71 and the fifth surface 72, and the entire inner opening 74a of the third opening 74 overlaps the second end surface 53b of the lens 5 when viewed from the Y direction. In this state, the third bonding member 11 is continuously disposed in at least a part of the region R31a between the second end surface 53b of the lens 5 and the inner opening 74a of the third opening 74, at least a part of the region R32 in the third opening 74 of the second support body 7, and at least a part of the region R33b on the fifth surface 72 of the second support body 7. Thereby, it is possible to thin the portion 111a, which is disposed in the region R31a between the second end surface 53b of the lens 5 and the inner opening 74a of the third opening 74, of the third bonding member 11 while suppressing protrusion of the third bonding member 11 from the region R31a between the second end surface 53b of the lens 5 and the inner opening 74a of the third opening 74 to the periphery (that is, while suppressing the amount of the portion 111b disposed in the region R31b between the second end surface 53b of the lens 5 and the fourth surface 71 of the second support body 7). Therefore, the axial deviation of the lens 5 due to the deformation of the third bonding member 11 is suppressed. Moreover, since the portion 112, which is disposed in the region R32 in the third opening 74 of the second support body 7, of the third bonding member 11 functions as a core and the portion 113b, which is disposed in the region R33b on the fifth surface 72 of the second support body 7, of the third bonding member 11 functions as an anchor, the bonding strength between the lens 5 and the second support body 7 is improved, and the axial deviation of the lens 5 in the direction perpendicular to the Y direction is suppressed.

As described above, according to the semiconductor laser device 1, the axial deviation of the lens 5 with respect to the semiconductor laser element 4 can be suppressed. In particular, in the semiconductor laser device 1, since the lens 5 adjusts the spread angle of the laser light L in the Z direction with respect to the laser light L emitted from each light-emitting point 4a, the tolerance of the axial deviation in the X direction is more severe than the tolerance of the axial deviation in the Y direction, and the tolerance of the axial deviation in the Z direction is more severe than the tolerance of the axial deviation in the X direction. Therefore, the above-described structure capable of suppressing the axial deviation of the lens 5 in the direction perpendicular to the Y direction is extremely effective.

Furthermore, in the semiconductor laser device 1, the first opening portion 64 is a through hole opened to the first surface 61 and the second surface 62. Thereby, since the first bonding member 8 easily stays in the region R12 in the through hole, the bonding strength between the lens 5 and the first support body 6 can be improved. Furthermore, formation of an air reservoir between the first support body 6 and the first bonding member 8 can be suppressed, and as a result, occurrence of the axial deviation of the lens 5 due to thermal expansion and thermal contraction of the air in the air reservoir can be suppressed.

Similarly, in the semiconductor laser device 1, the third opening 74 is a through hole opened to the fourth surface 71 and the fifth surface 72. Thereby, since the third bonding member 11 easily stays in the region R32 in the through hole, the bonding strength between the lens 5 and the second support body 7 can be improved. Furthermore, formation of an air reservoir between the second support body 7 and the third bonding member 11 can be suppressed, and as a result, occurrence of the axial deviation of the lens 5 due to thermal expansion and thermal contraction of the air in the air reservoir can be suppressed.

Furthermore, in the semiconductor laser device 1, in the first bonding member 8, the portion 81 disposed in at least a part of the region R11 between the first end surface 53a of the lens 5 and the plane including the first surface 61 of the first support body 6 is thinner than the portion 83 disposed in at least a part of the region R13 on the plane including the second surface 62 of the first support body 6. Thereby, since the thickness of the portion 81, which is disposed in the region R11 between the first end surface 53a of the lens 5 and the plane including the first surface 61 of the first support body 6, of the first bonding member 8 hardly varies, the axial deviation of the lens 5 due to the deformation of the first bonding member 8 can be suppressed. Furthermore, since the portion 83b, which is disposed in the region R13b on the second surface 62 of the first support body 6, of the first bonding member 8 functions as an anchor, the bonding strength between the lens 5 and the first support body 6 can be improved, and the axial deviation of the lens 5 in the direction perpendicular to the Y direction can be suppressed.

Similarly, in the semiconductor laser device 1, in the third bonding member 11, the portion 111 disposed in at least a part of the region R31 between the second end surface 53b of the lens 5 and the plane including the fourth surface 71 of the second support body 7 is thinner than the portion 113 disposed in at least a part of the region R33 on the plane including the fifth surface 72 of the second support body 7. Thereby, since the thickness of the portion 111, which is disposed in at least a part of the region R31 between the second end surface 53b of the lens 5 and the plane including the fourth surface 71 of the second support body 7, of the third bonding member 11 hardly varies, the axial deviation of the lens 5 due to the deformation of the third bonding member 11 can be suppressed. Furthermore, since the portion 113b, which is disposed in the region R33b on the fifth surface 72 of the second support body 7, of the third bonding member 11 functions as an anchor, the bonding strength between the lens 5 and the second support body 7 can be improved, and the axial deviation of the lens 5 in the direction perpendicular to the Y direction can be suppressed.

Furthermore, in the semiconductor laser device 1, the entire inner opening 64a of the first opening portion 64 overlaps the first end surface 53a of the lens 5 when viewed from the Y direction. Thereby, since the first bonding member 8 easily escapes from the region R11a between the first end surface 53a of the lens 5 and the inner opening 64a of the first opening portion 64 to the region R12 in the first opening portion 64, it is possible to suppress protrusion of the first bonding member 8 from the region R11a between the first end surface 53a of the lens 5 and the inner opening 64a of the first opening portion 64 to the periphery. Therefore, it is possible to reliably prevent the first bonding member 8 from adhering to the light-emitting surface 41a of the semiconductor laser element 4 and the light input surface 51 and the light output surface 52 of the lens 5. In particular, in the present embodiment, since the distance between the light input surface 51 of the lens 5 and the light-emitting surface 41a of the semiconductor laser element 4 is very small such as 1 mm or less, the above-described configuration capable of suppressing protrusion to the periphery of the first bonding member 8 is extremely effective.

Similarly, in the semiconductor laser device 1, the entire inner opening 74a of the third opening 74 overlaps the second end surface 53b of the lens 5 when viewed from the Y direction. Thereby, since the third bonding member 11 easily escapes from the region R31a between the second end surface 53b of the lens 5 and the inner opening 74a of the third opening 74 to the region R32 in the third opening 74, it is possible to suppress protrusion of the third bonding member 11 from the region R31a between the second end surface 53b of the lens 5 and the inner opening 74a of the third opening 74 to the periphery. Therefore, it is possible to reliably prevent the third bonding member 11 from adhering to the light-emitting surface 41a of the semiconductor laser element 4 and the light input surface 51 and the light output surface 52 of the lens 5. In particular, in the present embodiment, since the distance between the light input surface 51 of the lens 5 and the light-emitting surface 41a of the semiconductor laser element 4 is very small such as 1 mm or less, the above-described configuration capable of suppressing protrusion to the periphery of the third bonding member 11 is extremely effective.

Furthermore, in the semiconductor laser device 1, the first support body 6 has optical transparency. Thereby, it is possible to confirm the state of the portion 81, which is disposed in the region R11 between the first end surface 53a of the lens 5 and the plane including the first surface 61 of the first support body 6, of the first bonding member 8 and the portion 82, which is disposed in the region R12 in the first opening portion 64 of the first support body 6, of the first bonding member 8. Furthermore, when the first bonding member 8 and the second bonding member 9 are photocurable resins, the first bonding member 8 and the second bonding member 9 can be cured by irradiation with light through the first support body 6.

Similarly, in the semiconductor laser device 1, the second support body 7 has optical transparency. Thereby, it is possible to confirm the state of the portion 111, which is disposed in the region R31 between the second end surface 53b of the lens 5 and the plane including the fourth surface 71 of the second support body 7, of the third bonding member 11 and the portion 112, which is disposed in the region R32 in the third opening 74 of the second support body 7, of the third bonding member 11. Furthermore, when the third bonding member 11 and the fourth bonding member 12 are photocurable resins, the third bonding member 11 and the fourth bonding member 12 can be cured by irradiation with light through the second support body 7.

Furthermore, in the semiconductor laser device 1, the thickness of the first support body 6 in the Y direction is 2 mm or less. Thereby, it is possible to reliably dispose the first bonding member 8 in the region R12 in the first opening portion 64 of the first support body 6 while reducing the amount of the first bonding member 8.

Similarly, in the semiconductor laser device 1, the thickness of the second support body 7 in the Y direction is 2 mm or less. Thereby, it is possible to reliably dispose the third bonding member 11 in the region R32 in the third opening 74 of the second support body 7 while reducing the amount of the third bonding member 11.

Furthermore, in the semiconductor laser device 1, at least a part of the light output surface 52 of the lens 5 is offset from the first support body 6 when viewed from the Y direction. That is, at least a part of the light output surface 52 of the lens 5 protrudes from the first support body 6 in the X direction. Thereby, the first bonding member 8 can be prevented from adhering to the light output surface 52 of the lens 5.

Similarly, in the semiconductor laser device 1, at least a part of the light output surface 52 of the lens 5 is offset from the second support body 7 when viewed from the Y direction. That is, at least a part of the light output surface 52 of the lens 5 protrudes from the second support body 7 in the X direction. Thereby, the third bonding member 11 can be prevented from adhering to the light output surface 52 of the lens 5.

Furthermore, in the semiconductor laser device 1, the width of the inner opening 64a of the first opening portion 64 in the X direction is equal to the width of the inner opening 64a of the first opening portion 64 in the Z direction. Thereby, even when the portion 82, which is disposed in the region R12 in the first opening portion 64, of the first bonding member 8 is deformed, the axial deviation of the lens 5 particularly in the Z direction is suppressed, so that the lens 5 adjusting a spread angle of the laser light L in the Z direction can function suitably.

Similarly, in the semiconductor laser device 1, the width of the inner opening 74a of the third opening 74 in the X direction is equal to the width of the inner opening 74a of the third opening 74 in the Z direction. Thereby, even when the portion 112, which is disposed in the region R32 in the third opening 74, of the third bonding member 11 is deformed, the axial deviation of the lens 5 particularly in the Z direction is suppressed, so that the lens 5 adjusting a spread angle of the laser light L in the Z direction can function suitably.

Furthermore, in the semiconductor laser device 1, the first support body 6 formed separately from the submount 3 has the second opening portion 65 opened to the first surface 61 and the second surface 62, and the entire inner opening 65a of the second opening portion 65 overlaps the first side surface 32a of the submount 3 when viewed from the Y direction. In this state, the second bonding member 9 is continuously disposed in at least a part of the region R21a between the first side surface 32a of the submount 3 and the inner opening 65a of the second opening portion 65, at least a part of the region R22 in the second opening portion 65 of the first support body 6, and at least a part of the region R23b on the second surface 62 of the first support body 6. Thereby, structure (for example, shape and material) of each of the submount 3 and the first support body 6 can be appropriately configured. Furthermore, since the second bonding member 9 is disposed in the region R22 in the second opening portion 65 of the first support body 6, the bonding strength between the submount 3 and the first support body 6 can be improved.

Similarly, in the semiconductor laser device 1, the second support body 7 formed separately from the submount 3 has the fourth opening 75 opened to the fourth surface 71 and the fifth surface 72, and the entire inner opening 75a of the fourth opening 75 overlaps the second side surface 32b of the submount 3 when viewed from the Y direction. In this state, the fourth bonding member 12 is continuously disposed in at least a part of the region R41a between the second side surface 32b of the submount 3 and the inner opening 75a of the fourth opening 75, at least a part of the region R42 in the fourth opening 75 of the second support body 7, and at least a part of the region R43b on the fifth surface 72 of the second support body 7. Thereby, the structure of each of the submount 3 and the second support body 7 can be made suitable for each. Furthermore, since the fourth bonding member 12 is disposed in the region R42 in the fourth opening 75 of the second support body 7, the bonding strength between the submount 3 and the second support body 7 can be improved.

Furthermore, in the semiconductor laser device 1, in the first surface 61 of the first support body 6, the area of the region 61b overlapping the first side surface 32a of the submount 3 when viewed from the Y direction is larger than the area of the region 61a overlapping the first end surface 53a of the lens 5 when viewed from the Y direction, and the area of the inner opening 65a of the second opening portion 65 is larger than the area of the inner opening 64a of the first opening portion 64. Thereby, the stability of the support for the first support body 6 and the lens 5 can be improved. Furthermore, for example, in a case where the submount 3 and the first support body 6 are bonded after the lens 5 and the first support body 6 are bonded, even when the amount of the second bonding member 9 is increased so that the first support body 6 for alignment of the lens 5 with respect to the semiconductor laser element 4 can be easily moved, it is possible to suppress protrusion of the second bonding member 9 from the region 61b overlapping the first side surface 32a of the submount 3 when viewed from the Y direction of the first surface 61 of the first support body 6.

Similarly, in the semiconductor laser device 1, in the fourth surface 71 of the second support body 7, the area of the region 71b overlapping the second side surface 32b of the submount 3 when viewed from the Y direction is larger than the area of the region 71a overlapping the second end surface 53b of the lens 5 when viewed from the Y direction, and the area of the inner opening 75a of the fourth opening 75 is larger than the area of the inner opening 74a of the third opening 74. Thereby, the stability of supporting of the second support body 7 and the lens 5 can be improved. Furthermore, for example, in a case where the submount 3 and the second support body 7 are bonded after the lens 5 and the second support body 7 are bonded, even when the amount of the fourth bonding member 12 is increased so that the second support body 7 for alignment of the lens 5 with respect to the semiconductor laser element 4 can be easily moved, it is possible to suppress protrusion of the fourth bonding member 12 from the region 71b overlapping the second side surface 32b of the submount 3 when viewed from the Y direction of the fourth surface 71 of the second support body 7.

Furthermore, in the semiconductor laser device 1, the semiconductor laser element 4 has the plurality of light-emitting points 4a arranged in the Y direction, the lens 5 extends in the Y direction, and the light input surface 51 of the lens 5 faces the plurality of light-emitting points 4a in the X direction. Thereby, it is possible to suppress variation in the spread angle of the laser light L in the Z direction for the laser light L emitted from each light-emitting point 4a.

Furthermore, in the semiconductor laser device 1, the second opening portion 65 is located on the submount 3 side with respect to the lens 5 by a position of half the width of the first support body 6 in the X direction. Thereby, the second bonding member 9 is difficult to reach the light-emitting surface 41a of the semiconductor laser element 4. Furthermore, the alignment of the laser light L can be easily performed by adjusting the position of the first support body 6.

Similarly, in the semiconductor laser device 1, the fourth opening 75 is located on the submount 3 side with respect to the lens 5 by a position of half the width of the second support body 7 in the X direction. Thereby, the fourth bonding member 12 is difficult to reach the light-emitting surface 41a of the semiconductor laser element 4. Furthermore, the alignment of the laser light L can be easily performed by adjusting the position of the second support body 7.

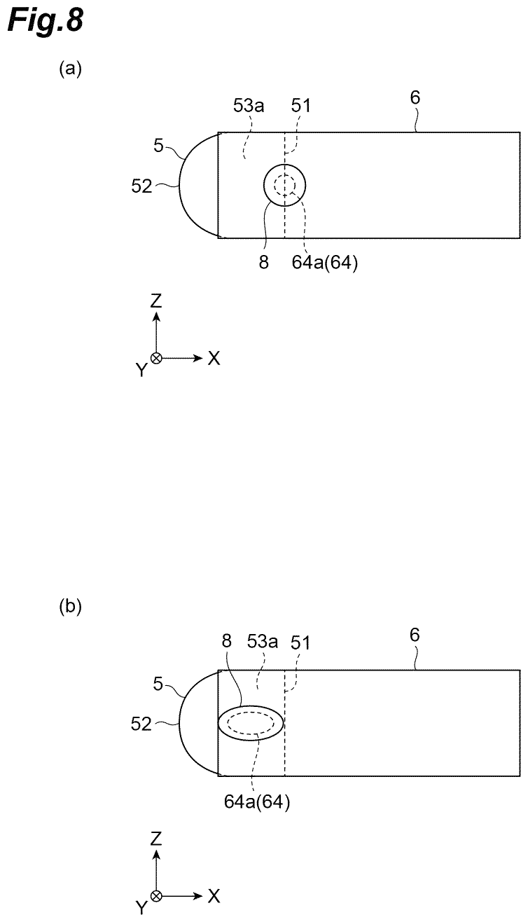

The present disclosure is not limited to the above embodiment. For example, as illustrated in (a) of FIG. 8, in the first support body 6, at least a part of the inner opening 64a of the first opening portion 64 may overlap the first end surface 53a of the lens 5 when viewed from the Y direction. Furthermore, in the first support body 6, at least a part of the inner opening 65a of the second opening portion 65 may overlap the first side surface 32a of the submount 3 when viewed from the Y direction.

Similarly, in the second support body 7, at least a part of the inner opening 74a of the third opening 74 may overlap the second end surface 53b of the lens 5 when viewed from the Y direction. Furthermore, in the second support body 7, at least a part of the inner opening 75a of the fourth opening 75 may overlap the second side surface 32b of the submount 3 when viewed from the Y direction.

Furthermore, as illustrated in (b) of FIG. 8, the width of the inner opening 64a of the first opening portion 64 in the X direction may be larger than the width of the inner opening 64a of the first opening portion 64 in the Z direction. That is, the width of the inner opening 64a of the first opening portion 64 in the X direction may be equal to or more than the width of the inner opening 64a of the first opening portion 64 in the Z direction. According to this, even when the portion 82, which is disposed in the region R12 in the first opening portion 64, of the first bonding member 8 is deformed, the axial deviation of the lens 5 particularly in the Z direction is suppressed, so that the lens 5 adjusting a spread angle of the laser light L in the Z direction can be suitably functioned. As an example, the inner opening 64a and the outer opening 64b of the first opening portion 64 have the same shape when viewed from the Y direction, the width of each of the inner opening 64a and the outer opening 64b in the X direction is about 0.4 mm, and the width of each of the inner opening 64a and the outer opening 64b in the Z direction is about 0.2 mm.

Similarly, the width of the inner opening 74a of the third opening 74 in the X direction may be larger than the width of the inner opening 74a of the third opening 74 in the Z direction. That is, the width of the inner opening 74a of the third opening 74 in the X direction may be equal to or more than the width of the inner opening 74a of the third opening 74 in the Z direction. According to this, even when the portion 112, which is disposed in the region R32 in the third opening 74, of the third bonding member 11 is deformed, the axial deviation of the lens 5 particularly in the Z direction is suppressed, so that the lens 5 adjusting a spread angle of the laser light L in the Z direction can be suitably functioned. As an example, the inner opening 74a and the outer opening 74b of the third opening 74 have the same shape when viewed from the Y direction, the width of each of the inner opening 74a and the outer opening 74b in the X direction is about 0.4 mm, and the width of each of the inner opening 74a and the outer opening 74b in the Z direction is about 0.2 mm.

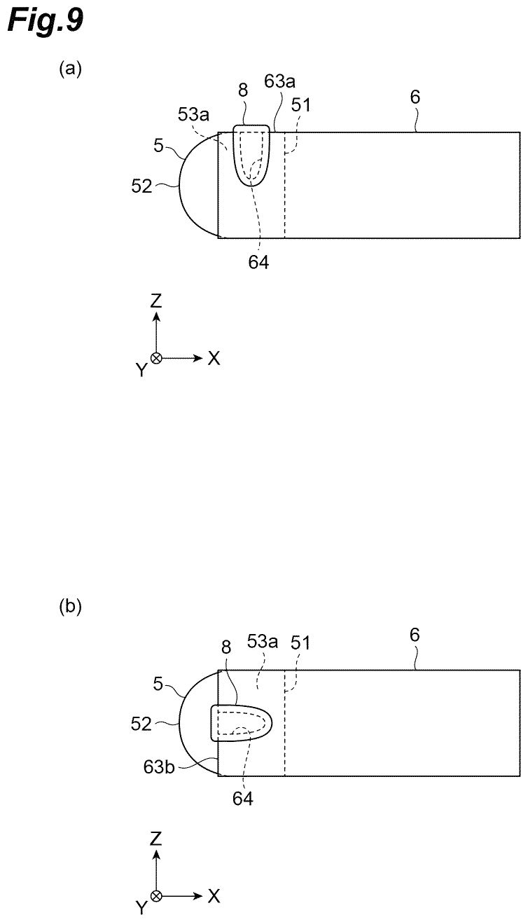

For example, as illustrated in (a) and (b) of FIG. 9, the first opening portion 64 may be a notch opened to the first surface 61 and the second surface 62 and opened to the third surface 63. According to this, since the first bonding member 8 easily escapes from the region R11a between the first end surface 53a of the lens 5 and the inner opening 64a of the first opening portion 64 to the notch side, it is possible to suppress protrusion of the first bonding member 8 from the region R11a between the first end surface 53a of the lens 5 and the inner opening 64a of the first opening portion 64 to the periphery. Furthermore, formation of an air reservoir between the first support body 6 and the first bonding member 8 can be suppressed, and as a result, occurrence of the axial deviation of the lens 5 due to thermal expansion and thermal contraction of the air in the air reservoir can be suppressed. As an example, the inner opening 64a and the outer opening 64b of the first opening portion 64 have the same shape when viewed from the Y direction, the width (maximum width) of each of the inner opening 64a and the outer opening 64b in a direction perpendicular to the depth direction of the notch is about 0.2 mm, and the width (maximum width) of each of the inner opening 64a and the outer opening 64b in a direction parallel to the depth direction of the notch is about 0.5 mm.

Similarly, the third opening 74 may be a notch opened to the fourth surface 71 and the fifth surface 72 and opened to the sixth surface 73. According to this, since the third bonding member 11 easily escapes from the region R31a between the second end surface 53b of the lens 5 and the inner opening 74a of the third opening 74 to the notch side, it is possible to suppress protrusion of the third bonding member 11 from the region R31a between the second end surface 53b of the lens 5 and the inner opening 74a of the third opening 74 to the periphery. Furthermore, formation of an air reservoir between the second support body 7 and the third bonding member 11 can be suppressed, and as a result, occurrence of the axial deviation of the lens 5 due to thermal expansion and thermal contraction of the air in the air reservoir can be suppressed. As an example, the inner opening 74a and the outer opening 74b of the third opening 74 have the same shape when viewed from the Y direction, the width (maximum width) of each of the inner opening 74a and the outer opening 74b in a direction perpendicular to the depth direction of the notch is about 0.2 mm, and the width (maximum width) of each of the inner opening 74a and the outer opening 74b in a direction parallel to the depth direction of the notch is about 0.5 mm.

In particular, as illustrated in (a) of FIG. 9, when the notch, which is the first opening portion 64, is opened to a region 63a located on one side of the third surface 63 of the first support body 6 in the Z direction when viewed from the Y direction, the effect as described below is obtained. That is, even when the first bonding member 8 protrudes from the region R12 in the notch to the region on the third surface 63 of the first support body 6, the first bonding member 8 can be prevented from adhering to the light input surface 51 and the light output surface 52 of the lens 5. The same applies to a case where the third opening 74 is a notch.

Furthermore, as illustrated in (b) of FIG. 9, when the notch, which is the first opening portion 64, is opened to a region 63b located on a side of the third surface 63 of the first support body 6 opposite to the semiconductor laser element 4 in the X direction when viewed from the Y direction, the effect as described below is obtained. That is, even when the portion 82, which is disposed in the region R12 in the notch, of the first bonding member 8 is deformed, the axial deviation of the lens 5 particularly in the Z direction is suppressed, so that the lens 5 adjusting a spread angle of the laser light L in the Z direction can be suitably functioned. The same applies to a case where the third opening 74 is a notch.

Furthermore, the first bonding member 8 may not be disposed in at least a part of the region R13b on the second surface 62 of the first support body 6 as long as it is continuously disposed in at least a part of the region R11a between the first end surface 53a of the lens 5 and the inner opening 64a of the first opening portion 64 and at least a part of the region R12 in the first opening portion 64 of the first support body 6. In this case, when the first bonding member 8 reaches the outer opening 64b of the second surface 62 in the first opening portion 64, the portion 82, which is disposed in the region R12 in the first opening portion 64 of the first support body 6, of the first bonding member 8 functions as a core, so that the bonding strength between the lens 5 and the first support body 6 can be improved, and the axial deviation of the lens 5 in the direction perpendicular to the Y direction can be suppressed. However, the first bonding member 8 may not reach the outer opening 64b of the first opening portion 64 as long as it is continuously disposed in at least a part of the region R11a and at least a part of the region R12.

Furthermore, the first bonding member 8 may not be disposed in at least a part of the region R11b between the first end surface 53a of the lens 5 and the first surface 61 of the first support body 6 as long as it is continuously disposed in at least a part of the region R11a between the first end surface 53a of the lens 5 and the inner opening 64a of the first opening portion 64 and at least a part of the region R12 in the first opening portion 64 of the first support body 6. Also in this case, the bonding strength between the lens 5 and the first support body 6 can be improved while suppressing the axial deviation of the lens 5 in the direction perpendicular to the Y direction. Note that the portion 81b of the first bonding member 8 may not have an annular shape, and the shape of the portion 81b is not particularly limited. However, from the viewpoint of securing the adhesive strength between the lens 5 and the first support body 6, the portion 81b preferably has an annular shape.

Similarly, the third bonding member 11 may not be disposed in at least a part of the region R33b on the fifth surface 72 of the second support body 7 as long as it is continuously disposed in at least a part of the region R31a between the second end surface 53b of the lens 5 and the inner opening 74a of the third opening 74 and at least a part of the region R32 in the third opening 74 of the second support body 7. In this case, when the third bonding member 11 reaches the outer opening 74b of the fifth surface 72 in the third opening 74, the portion 112, which is disposed in the region R32 in the third opening 74 of the second support body 7, of the third bonding member 11 functions as a core, so that the bonding strength between the lens 5 and the second support body 7 can be improved, and the axial deviation of the lens 5 in the direction perpendicular to the Y direction can be suppressed. However, the third bonding member 11 may not reach the outer opening 74b of the third opening 74 as long as it is continuously disposed in at least a part of the region R31a and at least a part of the region R32.

The third bonding member 11 may not be disposed in at least a part of the region R31b between the second end surface 53b of the lens 5 and the fourth surface 71 of the second support body 7 as long as it is continuously disposed in at least a part of the region R31a between the second end surface 53b of the lens 5 and the inner opening 74a of the third opening 74 and at least a part of the region R32 in the third opening 74 of the second support body 7. Also in this case, the bonding strength between the lens 5 and the second support body 7 can be improved while suppressing the axial deviation of the lens 5 in the direction perpendicular to the Y direction. Note that the portion 111b of the third bonding member 11 may not have an annular shape, and the shape of the portion 111b is not particularly limited. However, from the viewpoint of securing the adhesive strength between the lens 5 and the second support body 7, the portion 111b preferably has an annular shape.

Furthermore, the second bonding member 9 may not be disposed in at least a part of the region R23b on the second surface 62 of the first support body 6 as long as it is continuously disposed in at least a part of the region R21a between the first side surface 32a of the submount 3 and the inner opening 65a of the second opening portion 65 and at least a part of the region R22 in the second opening portion 65 of the first support body 6. In this case, the second bonding member 9 may or may not reach the outer opening 65b of the second surface 62 in the second opening portion 65.

Furthermore, the second bonding member 9 may not be disposed in at least a part of the region R21b between the first side surface 32a of the submount 3 and the first surface 61 of the first support body 6 as long as it is continuously disposed in at least a part of the region R21a between the first side surface 32a of the submount 3 and the inner opening 65a of the second opening portion 65 and at least a part of the region R22 in the second opening portion 65 of the first support body 6. Also in this case, the bonding strength between the submount 3 and the first support body 6 can be improved. Note that the portion 91b of the second bonding member 9 may not have an annular shape, and the shape of the portion 91b is not particularly limited. However, from the viewpoint of securing the adhesive strength between the submount 3 and the first support body 6, the portion 91b preferably has an annular shape.

Similarly, the fourth bonding member 12 may not be disposed in at least a part of the region R43b on the fifth surface 72 of the second support body 7 as long as it is continuously disposed in at least a part of the region R41a between the second side surface 32b of the submount 3 and the inner opening 75a of the fourth opening 75 and at least a part of the region R42 in the fourth opening 75 of the second support body 7. In this case, the fourth bonding member 12 may or may not reach the outer opening 75b on the fifth surface 72 side in the fourth opening 75.

Furthermore, the fourth bonding member 12 may not be disposed in at least a part of the region R41b between the second side surface 32b of the submount 3 and the fourth surface 71 of the second support body 7 as long as it is continuously disposed in at least a part of the region R41a between the second side surface 32b of the submount 3 and the inner opening 75a of the fourth opening 75 and at least a part of the region R42 in the fourth opening 75 of the second support body 7. Also in this case, the bonding strength between the submount 3 and the second support body 7 can be improved. Note that the portion 121b of the fourth bonding member 12 may not have an annular shape, and the shape of the portion 121b is not particularly limited. However, from the viewpoint of securing the adhesive strength between the submount 3 and the second support body 7, the portion 121b preferably has an annular shape.

Furthermore, the first support body 6 may be attached to the submount 3 via another member, or may be formed integrally with the submount 3. Similarly, the second support body 7 may be attached to the submount 3 via another member, or may be formed integrally with the submount 3. Furthermore, the semiconductor laser device 1 may include a base different from the submount 3. Furthermore, the base may be configured with a plurality of members. Furthermore, the semiconductor laser device 1 may not include the submount 3, but may include a heat sink as a base, and the first support body 6 and the second support body 7 may be attached to the heat sink. Furthermore, the semiconductor laser device 1 may not include the second support body 7 as long as it includes the first support body 6. Furthermore, the semiconductor laser element 4 may have one light-emitting point 4a.

In the above-described embodiment, the single first opening portion 64 is formed in the first support body 6, but a plurality of first opening portions 64 may be formed in the first support body 6. Furthermore, in the above-described embodiment, the single second opening portion 65 is formed in the first support body 6, but a plurality of second opening portions 65 may be formed in the first support body 6. Similarly, in the above-described embodiment, the single third opening 74 is formed in the second support body 7, but a plurality of third openings 74 may be formed in the second support body 7. Furthermore, in the above-described embodiment, the single fourth opening 75 is formed in the second support body 7, but a plurality of fourth openings 75 may be formed in the second support body 7.

Furthermore, the shape of the first opening portion 64 as a through hole is not limited to a cylindrical shape having a center line parallel to the Y direction, and may be other shapes such as a prismatic shape. For example, in the first opening portion 64, the outer opening 64b may be a through hole having a tapered shape which is smaller than the inner opening 64a. In this case, the first bonding member 8 is easily disposed in the first opening portion 64. Furthermore, the first opening portion 64 as a through hole may extend such that the center line is inclined with respect to the Y direction, or may be bent inside the first support body 6. The same applies to each of the second opening portion 65, the third opening 74, and the fourth opening 75.

Furthermore, from the viewpoint of securing the strength of the first support body 6, the width (maximum width) of each of the inner opening 64a and the outer opening 64b of the first opening portion 64 in the Z direction is preferably ½ or less of the width of the first support body 6 in the Z direction. Furthermore, from the viewpoint of securing a sufficient space for the first bonding member 8 to flow in, the width (maximum width) of each of the inner opening 64a and the outer opening 64b of the first opening portion 64 in the Z direction is preferably 1/10 or more of the width of the first support body 6 in the Z direction, and more preferably ⅕ or more of the width of the first support body 6 in the Z direction. The same applies to each of the second opening portion 65, the third opening 74, and the fourth opening 75.

Furthermore, at the time of manufacturing the semiconductor laser device 1, by disposing the first bonding member 8 in the region R11 (regions R11a and R11b) between the first end surface 53a of the lens 5 and the first surface 61 of the first support body 6, the first bonding member 8 may be moved to the region R12 in the first opening portion 64 of the first support body 6. In this case, by applying the first bonding member 8 to the first end surface 53a of the lens 5 or the first surface 61 of the first support body 6 and pressing one of the first end surface 53a and the first surface 61 against the other, the first bonding member 8 may be moved to the region R12 in the first opening portion 64. Alternatively, at the time of manufacturing the semiconductor laser device 1, by disposing the first bonding member 8 in the region R12 in the first opening portion 64 of the first support body 6, the first bonding member 8 may be moved to the region R11b between the first end surface 53a of the lens 5 and the first surface 61 of the first support body 6. In this case, the first bonding member 8 may be moved to the region R11b between the first end surface 53a and the first surface 61 by injecting the first bonding member 8 into the region R12 in the first opening portion 64 from the outer opening 64b side (that is, from the second surface 62 side) in a state where the first end surface 53a of the lens 5 and the first surface 61 of the first support body 6 are brought into contact with each other. When there is a slight gap between the first end surface 53a and the first surface 61, the first bonding member 8 can enter the region R11b between the first end surface 53a and the first surface 61 by capillary action. However, from the viewpoint that the first bonding member 8 is easily disposed in the region R11b, the former manufacturing method is preferable.

Similarly, at the time of manufacturing the semiconductor laser device 1, by disposing the third bonding member 11 in the region R31 (regions R31a and R31b) between the second end surface 53b of the lens 5 and the fourth surface 71 of the second support body 7, the third bonding member 11 may be moved to the region R32 in the third opening 74 of the second support body 7, or by disposing the third bonding member 11 in the region R32 in the third opening 74 of the second support body 7, the third bonding member 11 may be moved to the region R31b between the second end surface 53b of the lens 5 and the fourth surface 71 of the second support body 7. However, from the viewpoint that the third bonding member 11 is easily disposed in the region R31b, the former manufacturing method is preferable.

Furthermore, at the time of manufacturing the semiconductor laser device 1, by disposing the second bonding member 9 in the region R21 (regions R21a and R21b) between the first side surface 32a of the submount 3 and the first surface 61 of the first support body 6, the second bonding member 9 may be moved to the region R22 in the second opening portion 65 of the first support body 6, or by disposing the second bonding member 9 in the region R22 in the second opening portion 65 of the first support body 6, the second bonding member 9 may be moved to the region R21b between the first side surface 32a of the submount 3 and the first surface 61 of the first support body 6. However, from the viewpoint that the second bonding member 9 is easily disposed in the region R21b, the former manufacturing method is preferable.

Similarly, at the time of manufacturing the semiconductor laser device 1, by disposing the fourth bonding member 12 in the region R41 (regions R41a and R41b) between the second side surface 32b of the submount 3 and the fourth surface 71 of the second support body 7, the fourth bonding member 12 may be moved to the region R42 in the fourth opening 75 of the second support body 7, or by disposing the fourth bonding member 12 in the region R42 in the fourth opening 75 of the second support body 7, the fourth bonding member 12 may be moved to the region R41b between the second side surface 32b of the submount 3 and the fourth surface 71 of the second support body 7. However, from the viewpoint that the fourth bonding member 12 is easily disposed in the region R41b, the former manufacturing method is preferable.

Furthermore, at least a part of light output surface 52 of the lens 5 may protrude from the distal end 6a of the first support body 6 and the distal end 7a of the second support body 7 to one side in the Z direction when viewed from the Y direction. That is, at least a part of the light output surface 52 of the lens 5 may be offset from the first support body 6 and the second support body 7 in the direction perpendicular to the Y direction (a direction including the X direction and the Z direction) when viewed from the Y direction. In this case, the first bonding member 8 and the third bonding member 11 can be prevented from adhering to the light output surface 52 of the lens 5.

Furthermore, at least a part of the light input surface 51 of the lens 5 may protrude from the distal end 6a of the first support body 6 and the distal end 7a of the second support body 7 to one side in the Z direction when viewed from the Y direction. That is, at least a part of the light input surface 51 of the lens 5 may be offset from the first support body 6 and the second support body 7 in the direction perpendicular to the Y direction when viewed from the Y direction. In this case, the first bonding member 8 and the third bonding member 11 can be prevented from adhering to the light input surface 51 of the lens 5.

Furthermore, the light output surface 52 of the lens 5 may not be offset from the first support body 6 and the second support body 7 in the direction perpendicular to the Y direction when viewed from the Y direction. In this case, the entire first end surface 53a of the lens 5 may overlap the first surface 61 of the first support body 6 when viewed from the Y direction. Furthermore, the entire second end surface 53b of the lens 5 may overlap the fourth surface 71 of the second support body 7 when viewed from the Y direction.

### REFERENCE SIGNS LIST

1 Semiconductor laser device
3 Submount (base)
32a First side surface (side surface)
4 Semiconductor laser element
4a Light-emitting point
5 Lens
51 Light input surface
52 Light output surface
53a First end surface
53b Second end surface
6 First support body
61 First surface
61a, 61b Region
62 Second surface
63 Third surface
63a, 63b Region
64 First opening portion
64a Inner opening
64b Outer opening
65 Second opening portion
65a Inner opening
7 Second support body
71 Fourth surface
72 Fifth surface
74 Third opening
74a Inner opening
8 First bonding member
81, 82, 83 Portion
9 Second bonding member
11 Third bonding member
L Laser light
R11a, R11b, R12, R13b, R21a, R21b, R22, R31a, R31b, R32
Region

1. A semiconductor laser device comprising:
a base;
a semiconductor laser element disposed on the base and having at least one light-emitting point configured to emit laser light;
a lens having a light input surface facing the at least one light-emitting point in a first direction, a light output surface located on a side opposite to the light input surface in the first direction, a first end surface located on one side in a second direction perpendicular to the first direction, and a second end surface located on the other side in the second direction, and configured to adjust a spread angle of the laser light in a third direction perpendicular to both the first direction and the second direction;
a first support body having a first surface located on the first end surface side in the second direction and a second surface located on a side opposite to the first end surface in the second direction, and supporting the lens with respect to the base; and
a first bonding member bonding the lens and the first support body, wherein
the first support body has a first opening portion opened to the first surface and the second surface,
at least a part of an inner opening of the first opening portion on the first surface side overlaps the first end surface when viewed from the second direction, and
the first bonding member is continuously disposed in at least a part of a region between the first end surface and the inner opening of the first opening portion and at least a part of a region in the first opening portion.

2. The semiconductor laser device according to claim 1, wherein the first bonding member is continuously disposed in at least a part of a region between the first end surface and the first surface, at least a part of the region between the first end surface and the inner opening of the first opening portion, and at least a part of the region in the first opening portion.

3. The semiconductor laser device according to claim 1, wherein the first opening portion is a through hole opened to the first surface and the second surface.

4. The semiconductor laser device according to claim 1, wherein the first opening portion is a notch opened to the first surface and the second surface and opened to a third surface connecting the first surface and the second surface.

5. The semiconductor laser device according to claim 4, wherein the notch is opened to a region of the third surface located on a side opposite to the semiconductor laser element in the first direction when viewed from the second direction.

6. The semiconductor laser device according to claim 4, wherein the notch is opened to a region of the third surface located on one side in the third direction when viewed from the second direction.

7. The semiconductor laser device according to claim 1, wherein the first bonding member reaches an outer opening of the first opening portion on the second surface side.

8. The semiconductor laser device according to claim 1, wherein the first bonding member is continuously disposed in at least a part of the region between the first end surface and the inner opening of the first opening portion, at least a part of the region in the first opening portion, and at least a part of a region on the second surface.

9. The semiconductor laser device according to claim 8, wherein in the first bonding member, a portion disposed in at least a part of the region between the first end surface and the inner opening of the first opening portion is thinner than a portion disposed in at least a part of the region on the second surface.

10. The semiconductor laser device according to claim 1, wherein the entire inner opening of the first opening portion overlaps the first end surface when viewed from the second direction.

11. The semiconductor laser device according to claim 1, wherein the first support body has optical transparency.

12. The semiconductor laser device according to claim 1, wherein a thickness of the first support body in the second direction is 2 mm or less.

13. The semiconductor laser device according to claim 1, wherein at least a part of the light output surface is offset from the first support body when viewed from the second direction.

14. The semiconductor laser device according to claim 1, wherein a width of the inner opening of the first opening portion in the first direction is equal to or more than a width of the inner opening of the first opening portion in the third direction.

15. The semiconductor laser device according to claim 1, further comprising
a second bonding member bonding the base and the first support body formed separately from the base, wherein
the first support body has a second opening portion opened to the first surface and the second surface,
at least a part of an inner opening of the second opening portion on the first surface side overlaps a side surface of the base when viewed from the second direction, and
the second bonding member is continuously disposed in at least a part of a region between the side surface and the inner opening of the second opening portion and at least a part of a region in the second opening portion.

16. The semiconductor laser device according to claim 15, wherein the second bonding member is continuously disposed in at least a part of a region between the side surface and the first surface, at least a part of the region between the side surface and the inner opening of the second opening portion, and at least a part of the region in the second opening portion.

17. The semiconductor laser device according to claim 15, wherein in the first surface, an area of a region overlapping the side surface when viewed from the second direction is larger than an area of a region overlapping the first end surface when viewed from the second direction, and
an area of the inner opening of the second opening portion is larger than an area of the inner opening of the first opening portion.

18. The semiconductor laser device according to claim 1, further comprising:
a second support body having a fourth surface located on the second end surface side in the second direction and a fifth surface located on a side opposite to the second end surface in the second direction, and supporting the lens with respect to the base; and
a third bonding member bonding the lens and the second support body, wherein
the second support body has a third opening opened to the fourth surface and the fifth surface,
at least a part of an inner opening of the third opening on the fourth surface side overlaps the second end surface when viewed from the second direction, and
the third bonding member is continuously disposed in at least a part of a region between the second end surface and the inner opening of the third opening and at least a part of a region in the third opening.

19. The semiconductor laser device according to claim 18, wherein the third bonding member is continuously disposed in at least a part of a region between the second end surface and the fourth surface, at least a part of the region between the second end surface and the inner opening of the third opening, and at least a part of the region in the third opening.

20. The semiconductor laser device according to claim 1, wherein the semiconductor laser element has a plurality of light-emitting points arranged in the second direction,
the lens extends in the second direction, and
the light input surface faces the plurality of light-emitting points in the first direction.
